(19) United States
(12) Patent Application Publication
(10) Pub. No.: US 2012/0161100 A1
(43) Pub. Date: Jun. 28, 2012

(54) LIGHT EMITTING DIODE AND MAKING METHOD THEREOF

(75) Inventor: CHIA-LING HSU, Tu-Cheng (TW)

(73) Assignee: HON HAI PRECISION INDUSTRY CO., LTD., Tu-Cheng (TW)

(21) Appl. No.: 13/151,285

(22) Filed: Jun. 2, 2011

(30) Foreign Application Priority Data
Dec. 27, 2010 (TW) 99146005

(51) Int. Cl. H01L 33/04

(52) U.S. Cl. 257/13; 438/47; 257/76; 257/E33.005

(57) ABSTRACT

An LED includes a substrate, an N-type GaN layer, an insulation layer, an N-type GaN nano-wire layer, a quantum well layer and a P-type GaN nano-wire layer. The N-type GaN layer and the insulation layer are arranged on the substrate in turn. At least one groove is formed on a top surface of the insulation layer, therefore, part of the N-type GaN layer is exposed. The N-type GaN nano-wire layer is formed on the groove of the insulation layer, and part of the N-type GaN nano-wire layer is protruded from the insulation layer. The quantum well layer and the P-type GaN nano-wire layer are coated on the part of the N-type GaN nano-wire layer which is protruded from the insulation layer. The present invention also relates to a method for making an LED.

### BACKGROUND

1. Technical Field

The present disclosure relates to solid state light emitting devices and, more particularly, to a light emitting diode (LED) with high quantum efficiency and making method thereof.

2. Description of Related Art

Nowadays, LEDs (i.e., light emitting diodes) have the advantages of low-power consumption and long life-span, etc, and thus are widely used for display, backlight, outdoor illumination, automobile illumination, etc.

LED includes a first semiconductor layer (such as N-type semiconductor layer), a second semiconductor layer (such as P-type semiconductor layer), and a quantum well layer arranged between the first semiconductor layer and the second semiconductor layer. Generally, the quantum well layer of the LED is formed in two-dimension, therefore, the quantum efficiency of the LED decreases because of surface defects.

Therefore, it is desirable to provide an LED and making method thereof which can overcome the above-mentioned shortcomings.

### BRIEF DESCRIPTION OF THE DRAWINGS

FIG. 1 is a cross-sectional view of an embodiment of an LED of the present disclosure.

FIG. 2 shows a flow chart of an embodiment of a method for manufacturing the LED of FIG. 1.

### DETAILED DESCRIPTION

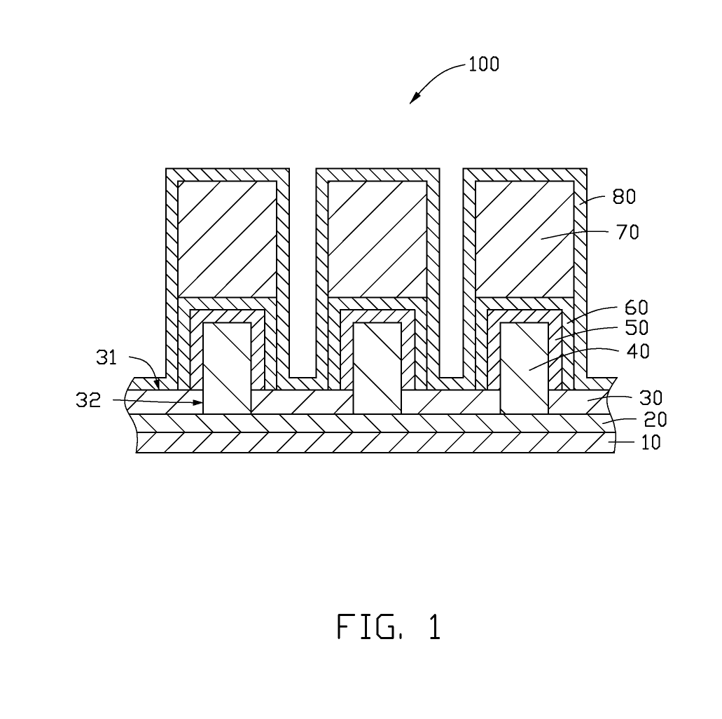

Referring to FIG. 1, an LED 100 in accordance with an embodiment of the present disclosure is disclosed. The LED 100 includes a substrate 10, an N-type GaN layer 20, an insulation layer 30, an N-type GaN nano-wire layer 40, a quantum well layer 50, a P-type GaN nano-wire layer 60, a P-type ZnO nano-wire layer 70 and a P-type transparent electrode layer 80.

The substrate 10 beneficially is a single crystal plate and can be made from a material of sapphire, silicon carbide (SiC), silicon (Si), gallium arsenide (GaAs), lithium aluminate (LiAlO₂), magnesium oxide (MgO), zinc oxide (ZnO), GaN, aluminum nitride (AlN) or indium nitride (InN), etc. In the present embodiment, the substrate 10 is single crystal alumina.

The N-type GaN layer 20 is formed on a top surface of the substrate 10, and is used as an N-type electrode of the LED 100.

The insulation layer 30 is formed on a top surface of the N-type GaN layer 20, and has a top surface 31 far away from the N-type GaN layer 20. The insulation layer 30 defines a plurality of grooves 32 at the top surface 31. A depth of the grooves 32 is equal to that of the insulation layer 30; therefore, a top surface of the N-type GaN layer 20 is partially exposed out from the grooves 32. In the present embodiment, the grooves 32 are formed by etching and anodic aluminum oxide (AAO) is used as etching mask. In the present embodiment, the grooves 32 are arranged in an array and uniformity spaced from each other. Openings of the grooves 32 are equivalent. The insulation layer 30 is SiO₂ layer.

The N-type GaN nano-wire layer 40 is arranged in the grooves 32 and contacts the exposed part of the N-type GaN layer 20. A height of the N-type GaN nano-wire layer 40 is higher than the depth of the grooves 32; therefore, the N-type GaN nano-wire layer 40 is formed as a number of islands projected from the grooves 32. In the present embodiment, heights of the islands of the N-type GaN nano-wire layer 40 are equivalent; therefore, top surfaces of the islands of the N-type GaN nano-wire layer 40 are co-planarity.

The quantum well layer 50 is formed on and encloses the N-type GaN nano-wire layer 40. In the present embodiment, the quantum well layer 50 is multi-GaInN quantum well layer, and is formed via epitaxy.

The P-type GaN nano-wire layer 60 is formed on an outer surface of and encloses the quantum well layer 50. The P-type ZnO nano-wire layer 70 is arranged on a top surface of the P-type GaN nano-wire layer 60 which is far away from the quantum well layer 50. The P-type ZnO nano-wire layer 70 is used for improving the light extraction efficiency of the LED 100.

The P-type transparent electrode layer 80 is formed on an outer surface of the P-type ZnO nano-wire layer 70 and an outer circumambient surface of the P-type GaN nano-wire layer 60. The P-type transparent electrode layer 80 encloses the P-type ZnO nano-wire layer 70 and the P-type GaN nano-wire layer 60. In the present embodiment, the P-type transparent electrode layer 80 is P-type adulterated ZnO layer and act as the P-type electrode of the LED 100.

The N-type GaN nano-wire layer 40 and the P-type GaN nano-wire layer 60 are one-dimension structure, in other words, the LED 100 has a profile that varies in one dimension; therefore, it can reduce the surface defects of the LED 100, and improve the quantum efficiency of the LED 100. Furthermore, the P-type ZnO nano-wire layer 70 can improve the light extraction efficiency of the LED 100.

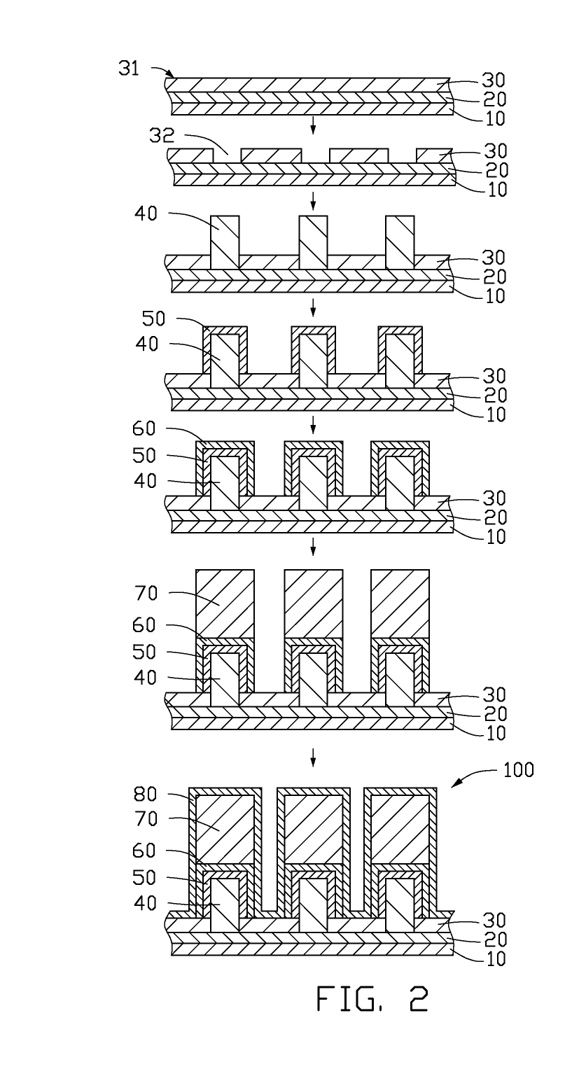

Referring to FIG. 2, a method for manufacturing the LED 100 in accordance with an exemplary embodiment is also disclosed, which includes the following steps.

The first step is to provide a substrate 10. In the present embodiment, the substrate 10 is single crystal alumina.

The second step is to form an N-type GaN layer 20 on the substrate 10. The N-type GaN layer 20 is configured as N-type electrode of the LED 100.

The third step is to form an insulation layer 30 on the N-type GaN layer 20, and form at least one groove 32 at a top surface 31 of the insulation layer 30. In the present embodiment, the insulation layer 30 has a top surface 31 far away from the N-type GaN layer 20, and the insulation layer 30 defines a plurality of grooves 32 at the top surface 31, and a top surface of the N-type GaN layer 20 is partially exposed out from the grooves 32. In the present embodiment, the grooves 32 are formed by etching and anodic aluminum oxide (AAO) is used as etching mask. The grooves 32 are arranged in an array and uniformity spaced from each other. Opening of the grooves 32 are equivalent. The insulation layer 30 is SiO₂ layer.

The fourth step is to form an N-type GaN nano-wire layer 40 in the grooves 32, with a top of the N-type GaN nano-wire layer 40 being exposed out from the grooves 32. In the present embodiment, the N-type GaN nano-wire layer 40 is formed as a number of islands projected from the grooves 32. The heights of the islands of the N-type GaN nano-wire layer 40 are equivalent; therefore, top surfaces of the islands of the N-type GaN nano-wire layer 40 are co-planarity.

The fifth step is to form a quantum well layer 50 on an outer surface of the N-type GaN nano-wire layer 40. In the present embodiment, the quantum well layer 50 is multi-GaInN quantum well layer, and formed via epitaxy.

The sixth step is to form a P-type GaN nano-wire layer 60 on an outer surface of the quantum well layer 50.

The seventh step is to form a P-type ZnO nano-wire layer 70 on a top surface of the P-type GaN nano-wire layer 60 which is far away from the quantum well layer 50. The P-type ZnO nano-wire layer 70 is used for improving the light extraction efficiency of the LED 100.

The eighth step is form a P-type transparent electrode layer 80 on an outer surface of the P-type ZnO nano-wire layer 70 and an outer circumambient surface of the P-type GaN nano-wire layer 60. In the present embodiment, the P-type transparent electrode layer 80 covers an outer surface of the insulation layer 30. The P-type transparent electrode layer 80 is P-type adulterated ZnO layer and act as the P-type electrode of the LED 100.

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. An LED, comprising:
a substrate;
an N-type GaN layer formed on the substrate having a top surface;
an insulation layer formed on the top surface of the N-type GaN layer, at least one groove extending through the insulation layer to the N-type GaN layer;
an N-type GaN nano-wire layer formed in the at least one groove, a part of the N-type GaN nano-wire layer extending beyond the groove;
a quantum well layer formed on an outer surface of the part of the N-type GaN nano-wire layer; and
a P-type GaN nano-wire layer formed on an outer surface of the quantum well layer.

2. The LED of claim 1, further comprising a P-type transparent electrode layer formed on an outer surface of the P-type GaN nano-wire layer.

3. The LED of claim 2, further comprising a P-type ZnO nano-wire layer formed between and contacts the P-type GaN nano-wire layer and the P-type ZnO nano-wire layer.

4. The LED of claim 2, wherein the P-type transparent electrode layer is P-type adulterated ZnO layer.

5. The LED of claim 1, wherein the insulation layer is SiO₂ layer.

6. A method for manufacturing an LED comprising:
providing a substrate;
forming an N-type GaN layer on the substrate;
forming an insulation layer on the N-type GaN layer with at least one groove extending therethrough to expose a part of the N-type GaN layer;
forming an N-type GaN nano-wire layer in the groove, one end of the N-type GaN nano-wire layer contacting the exposed part of the N-type GaN layer and the other end of the N-type GaN nano-wire layer projecting out the at least one groove of the insulating layer;
forming a quantum well layer on an outer surface of the N-type GaN nano-wire layer; and
forming a P-type GaN nano-wire layer on an outer surface of the quantum well layer.

7. The method for manufacturing an LED of claim 6, further comprising forming a P-type transparent electrode layer on an outer surface of the P-type GaN nano-wire layer.

8. The method for manufacturing an LED of claim 6, further comprising forming a P-type ZnO nano-wire layer on a top surface of the P-type GaN nano-wire layer; and forming a P-type transparent electrode layer on an outer surface of the P-type ZnO nano-wire layer.

9. The method for manufacturing an LED of claim 6, wherein the P-type transparent electrode layer is P-type adulterated ZnO layer.

10. The method for manufacturing an LED of claim 6, wherein the insulation layer is SiO₂ layer.

11. The method for manufacturing an LED of claim 6, wherein the groove is formed by etching and Anodic Aluminum oxide (AAO) is used as mask.
